(19) United States
(12) Patent Application Publication
(10) Pub. No.: US 2002/0126457 A1
(43) Pub. Date: Sep. 12, 2002

(54) Junction circuit for auxiliary device module and auxiliary device module

(75) Inventor: Isao Kameyama, Shizuoka (JP)

Correspondence Address: ARMSTRONG,WESTERMAN & HATTORI, LLP, 1725 K STREET, NW., SUITE 1000, WASHINGTON, DC, 20006, US

(73) Assignee: Yazaki Corporation, Tokyo (JP)

(21) Appl. No.: 10/092,298

(22) Filed: Mar. 7, 2002

(30) Foreign Application Priority Data
Mar. 9, 2001 (JP) 2001-66665

(51) Int. Cl. H05K 7/00

(52) U.S. Cl. 361/728

(57) ABSTRACT

To solve a trouble of electric wires bitten by a base board and a case in assembling process, an auxiliary device module z comprises a base board 2 with a terminal 8v mounted on an auxiliary device, a case 3, and a junction circuit 5 including a first electric connecting portion 31 with a terminal 8x, a second electric connecting portion 40 with a terminal 8y and a base board 6c. The case 3 is formed with a connector housing 33 correspondingly to the first electric connecting portion 31. A connector 30 is contained in the case 3 by mounting the first electric connecting portion 31 on the connector housing 33. The terminal 8v of the base board 2 and the other terminal 8y of the second electric connecting portion 40 are connected by mounting the base board 2 on the case 3.

### BACKGROUND OF THE INVENTION

1. Field of the Invention

This invention relates to an auxiliary device module, including an auxiliary device, such as a car-mount type CCD camera, a base board for the auxiliary device and a case, which can be connected removably with a corresponded mating device by means of a connector and is prevented to bite an electric wire when the auxiliary device module is assembled, and a junction circuit mounted on the auxiliary device module.

2. Description of the Related Art

A camera module Y, Z by prior art will be described with reference to FIGS. 8-11. FIG. 8 is a partial expanded view of a wiring harness 4 provided with a clamp 50 having an O-ring 51. Generally, a wiring harness in a car means a bundles electric wiring of an electric circuit in a car other than a high voltage electric circuit and a starting circuit. However, a wiring harness herein is defined an electric wiring assembly in which wiring components including an electric wire are integrated to be mounted easily in a car assembling line.

The O-ring 51, shown in FIG. 8, is mounted on the clamp 50 to keep air-tightness of a camera case 3. when the clamp 50 is mounted on the camera case 3. A clamp means a part which is used to mount a kind of an electric wire, such as a wiring harness, on a corresponding structure, such as a car body. The clamp means herein a binder to mount and fix an objective part on.

The clamp 50 is provided with a thread portion 50a to fix the clamp 50 securely on the camera case 30, a hexagon head 50b to be used for screwing operation to fix the clamp 50 on the camera case 3, and a flange 50c to give clamping force between the clamp 50 and the camera case 3, and perform an important part for air-tightening by the O-ring 51.

A throughhole 50d is provided inside the clamp 50 to pass a kind of an electric wire, such as cables 4a, 4a′ therethrough. Electric wires 4a, 4′, such as cables 4a, 4a′ including a drain wire 4a′, pass through the throughhole 50d of the clamp 50 with the O-ring 51, as shown in FIG. 8, and each end of the cables 4a, 4a′ is provided with a terminal TL1. The terminals TL1 are respectively received into a connector housing. Thus, a connector CR1 is formed at the end of the wiring harness 4, as shown in FIG. 9. The terminal means an electrode.

Describing a connector housing simply, a connector housing is defined as an electrical insulating component which holds terminals respectively in specific arrangement and insulates terminals respectively from each terminal and other electrical conductive members and generally has a receiving portion for a terminal. A connector is defined as a component which is provided with electrical connecting components, such as a connector housing, a terminal and an electric wire, and is used for electrical connecting.

The clamp 50, shown in FIG. 8, is provided with a potting process PG after the cables 4a, 4a′ are passed through the throughhole 50d of the clamp 50. Describing the potting process simply, the potting process is defined as sealing by means of pouring soft rubber, such as epoxy polymer, or soft resin into a space to be required.

Providing a potting process PG, the cables 4a, 4a′ can be sealed completely on respective wires so that infiltrating of water and dust into inside of the camera case 3 or a camera 1 can be prevented. Sealing performance for an area provided with a potting process PG is tested by water leakage checking for air-tightness or water-tightness.

FIGS. 9 and 10 are perspective views for assembling camera modules Y, Z having a car-mount-type CCD camera 1 by prior art. The camera module Y with the car-mount-type CCD camera by prior art will be described simply here. The camera module Y includes the camera 1 such as a car-mount-type CCD camera and a base board 2 mounted with the camera 1. The camera module Z is provided with the camera module Y having the camera 1 and the base board 2, the camera case 3 mounted with the camera module Y and the wiring harness 4 formed with bound various cables 4a, 4a′.

FIG. 9 and FIG. 10 show assembling process of the camera module Z having the car-mount type CCD camera 1 by prior art. FIG. 10 is a perspective view, showing wrong condition when the camera module Y, having the camera 1 and the base board 2, is mounted on the camera case 3. FIG. 11 is a conceptual drawing, showing a condition of mounting the wiring harness 4 on the camera case 3 through the clamp 50 by partially expanded sectional view, taken along the line R-R.

Each part of the camera module Z by prior art shown in FIGS. 9-11 is described herein in detail. The camera 1, as shown in FIGS. 9, 10, is provided with a lens 1a and a lens area portion 1b to hold the lens 1a. The base board 2 mounted with the camera 1 includes mainly a baseboard body 2′ provided with electric components such as connectors for electrical connecting.

The base board 2, mounted with the CCD camera 1, of the camera module Y is provided with a connector CR2. The connector CR2, which is a kind of electric components, is mounted on the base board body 2′ by soldering or fastenings such as screws. The base board body 2′ is also provided at four locations in the vicinity of four corners thereof with mounting holes 2b for fixing the base board 2 on the camera case 3 by fastenings such as screws SC1.

The camera case 3, manufactured by aluminum die-cast, is formed with a bottom wall 3c and side walls 3d, 3d′ standing around the bottom wall to provide a receiving section 3e. The side wall 3d′ is provided with a cylindrical projection 3h for fixing the clamp 50 and sealing the camera case 3. The camera case 3 is provided on four corners of inside of the receiving section 3e with screw fixing bodies 3a for fixing the base board 2 mounted with the camera 1 thereon. Each screw fixing body 3a has a tapped hole 3b.

Joint structure of the clamp 50 and the camera case 3, shown in FIGS. 9, 10, is described herein in detail with reference to FIG. 11. The camera case 3 is provided on the side wall 3d′ with a through hole 3f for putting the wiring harness 4 formed by bound cables 4a, 4a′ through. The through hole 3f is formed inside wall thereof with internal tread portion to combine with the thread portion 50a of the clamp 50 for fastening securely.

The clamp 50 with cables 4a, 4a′, shown in FIG. 8, therethrough is mounted in the through hole 3f formed on the side wall 3d′ of the camera case 3. Combining the thread portion 50a of the clamp 50 and the through hole 3f, formed with thread, of the camera case 3, the clamp 50 with wiring harness 4, shown in FIG. 11, therethrough is fixed on the camera case 3.

The camera case 3 is provided around the through hole 3f with the cylindrical projection 3h for guiding the clamp 50 with the O-ring 11, mentioned above, into the through hole 3f. The cylindrical projection 3h performs shield plate to keep hermetic sealing by the O-ring 51 mounted on the clamp 50 and to prevent infiltration of water or dust from outside.

The wiring harness 4, as shown in FIG. 11, connects the camera case 3 and a non-waterproof connector CR3 mounted in an inside-of-car V. The drain wire 4a′ branched at a middle portion of the wiring harness 4 is provided at the end thereof with a terminal TL2 and the terminal TL2 is fixed on a frame of a car body B by means of a screw SC2. Thus, the drain wire 4a performs earth ground.

Connecting the connector CR1, which is formed by inserting the terminal of the cables 4a, 4a′ into connector housing, and the connector CR2 mounted on the base board 2 builds a couple of male-and-female connectors and connects electrically the cables 4a, 4a′. and the camera 1 such as a car-mount-type CCD camera 1. Thus, the base board 2 with the camera 1, the wiring harness 4, the non-waterproof connector CR3 mounted in the inside-of-car V, the drain wire 4a′ and the like are respectively connected electrically.

The wiring harness 4 is provided at a middle area thereof with a grommet (not shown). The grommet is an annular rubber part to protect a wiring harness, a tube, a hose or a cable from an edge of a throughhole provided in a car body or a casing and/or to be used for waterproof, dust proof or sound proof. Grommets are also used as a sealing member for waterproof or dust proof. Grommets are provided when a wiring harness is passed through from inside of a car cabin to outside or from inside of a car cabin to an engine room or a luggage room.

An example of assembling process for the camera module Z having a car-mount-type CCD camera 1 by prior art is described herein in detail. The clamp 50 with the O-ring 51 is attached to the wiring harness 4, shown in FIG. 11. After inserting the wiring harness 4 formed by bound cables 4a, 4a′ through the throughhole 50d of the clamp 50, the wiring harness 4 and the clamps 50 are temporally fixed.

On a portion of the wiring harness 4, which is placed inside of the camera case 3 more inner from the clamp 50, a tube 4d for binding and protecting cables 4a, 4a′ is cleaved by a cutter or the like for pulling the cables 4a, 4a′ out from the tube 4d. The terminals TL1 are joined with the end of respective cables 4a, 4a′ and are received in the connector housing to build up the connector CR1, shown in FIG. 9.

To improve sealing performance of the wiring harness 4 and the clamp 50, as mentioned above, potting process PG by pouring resign or rubber into the throughhole 50d of the clamp 50 is done as shown in FIG. 8 and then the wiring harness and the clamp is fixed together. The potting process shown in FIGS. 8 and 11 enhances airtight performance of the camera case 3.

The clamp 50 is fixed at a suitable position of the wiring harness 4 for allowing the cables 4a, 4a′ to have an extra length to connect the camera case 3 and the base board 2, as shown in FIGS. 9, 10.

The clamp 50, in which the cables 4a, 4a′ are inserted, as mentioned above, is mounted into the through hole 3f of the camera case 3, as shown in FIG. 11. Thereafter, combining the thread portion 50a of the clamp 50 having the O-ring 51 with the through hole 3f, i.e. the treaded hole, of the camera case 3, the clamp 50 is fixed on the camera case 3 as shown in FIGS. 9-11. The O-ring 51 and potting process PG give air-tightness and sealing performance of the camera case 3, as shown in FIG. 11.

After above operation, the camera module Y, which means the base board 2 mounted with the camera 1, is set in the camera case 3. The operation process comprises the first step of connecting the connector CR1, which is joined with the wiring harness 4, with the connector CR2, which is mounted on the base board body 2′, as shown in FIGS. 9, 10, to be a couple of male-female connectors.

After connecting connectors mentioned above, the camera module Y is mounted on the camera case 3. Regarding the mounting process, the camera module Y, which is provided with the camera 1 and the base board 2, is mounted on the camera case 3 to place the through holes 2b provided in the base board 2 correspondingly to the tapped holes 3b provided on the four corners of the camera case 3.

Inserting the screws SC1 into each the through hole 2b provided in the base board body 2′, the screws are turned by a screw fastening means. Then, the screws SC1 go into the tapped holes 3b provided on the camera case 3. Thus, the base board 2 having the camera 1, which means the camera module Y, is fixed on the camera case 3 and then the camera module Z is assembled.

When looking at related arts, J.P.A. No. H1-183005 and J.P.A. No. H4-208588 exist.

J.P.A. Laid-open H1-183005 describes a wiring component which can connect electrically with an electric devices for a car and discloses improvement on a wiring component effective to place a plurality of electric devices on an equipment frame.

J.P.A. Laid-open H4-208588 describes an electric circuit module which means an electric device to integrate wired circuit units and discloses a structure of a flexible printed board module. The flexible printed board module includes a flexible printed board, on which electric components are mounted, is over-molded at once by a plurality of molding machines and is folded so as to make molded portions face to each other. The molded portions are provided with a convex portion and a concave portion which are joined for fixing.

### Objects to be Solved

Assembling a camera module Z by prior art, as shown in FIGS. 9 and 10, requires operation of passing the cables 4a, 4a′ from outside of the camera case 3 into the receiving section 3e of the camera case 3 through the throughhole 3f of the camera case 3.

Furthermore, operation of screwing the clamp 50 mounted on the wiring harness 4 into the thread portion provided on the throughhole of the camera case 3 to fix the clamp 50 mounted on the wiring harness 4 on the camera case 3 is required to improve sealing performance of the throughhole 3f of the camera case 3.

Operation of connecting the connector CR1 provided at the end of the cables 4a, 4a′ and the connector CR2 mounted on the base board 2 for electrical connecting is also required. Therefore, whole assembling for the camera module Z requires manual operation and then an operator is forced to have complicated assembling operation. Thus, assembling of the camera module Z by prior art requires a lot of complicated operation and then necessary for much product tact and manufacturing time makes low efficiency of production.

FIG. 10 is a perspective view at a time of bad situation occurred during mounting the camera module Y on the camera case3. During mounting the camera module Y by prior art on the camera case 3, it is feared that the cables 4a, 4a′ are bitten by the camera module Y and the camera case 3 as shown in FIG. 10.

The cable 4a or the drain wire 4a′, which are bitten by a gap between the camera module Y and the camera. case 3 in assembling process, may possibly have breaking of wire inside thereof. Therefore, a camera module Z with such bitten cable 4a or drain wire 4a′ is judged as a defective unit.

Abandoning such unfinished products is undesirable for terrestrial environment and wasteful on manufacturing. Then, reassembling such camera module Z to replace components related with an electric wire 4, such as a wiring harness 4, provided with a cable 4a, a drain wire 4a′ and a tube 4d, and a clamp 50 is required.

When the camera module Z by prior art, shown in FIGS. 9-11, is broken or an electric component in inside of the camera case 3 is in a malfunction, the whole camera module Z including a wiring harness 4 is required to be removed for disassembling, analyzing and repairing.. Such operation for removing or replacing a camera module Z is troublesome.

Thus, for maintaining a camera 1 by prior art, whole camera module Z including a wiring harness 4 must be removed and much time and working for the operation are required. Such operation for removing or repairing a camera module Z to recycle it for environmental reason may be unfeasible because of a lot of troubles.

To overcome the above drawback, one object of this invention is to provide a junction circuit which is mounted on an auxiliary device module and the auxiliary device module which can solve the trouble of biting electric wires such as cables between a case and abase boardwhen assembling an auxiliary device module, to remove easily a case, which is provided with an auxiliary device such as a camera and a base board, and a corresponded device, which is connected with this case, by using a connector.

### SUMMARY OF THE INVENTION

### How to Attain the Object

In order to attain the objects, a junction circuit for an auxiliary device module comprises a first base portion provided with a terminal mount hole for inserting a terminal to build a first electrical connecting portion, a second base portion provided with a terminal mount hole for inserting a terminal to build a second electrical connecting portion, and a base board being integrated with the first base portion and the second base portion, wherein the terminal of the first electrical connecting portion and the terminal of the second electrical connecting portion are electrically connected through a conductive printed wire of a flexible base, i.e. a flexible printed circuit board.

Advantageously, soldering a rear end of the terminal provided in the first electrical connecting portion and one end of the conductive printed wire of the flexible base and soldering a rear end of the terminal provided in the second electrical connecting portion and the other end of the conductive printed wire of the flexible base are effective.

Advantageously, providing the conductive printed wire on an insulating soft sheet as a flexible printed circuit board and connecting the flexible printed circuit board, which is folded at a predetermined area, with the first electrical connecting portion and the second electrical connecting portion are effective.

Advantageously, providing a board mounting hole in the junction circuit for the auxiliary device module correspondingly to a mount area of a case mounted with the junction circuit for the auxiliary device module is effective.

An auxiliary device module comprises a base board provided with a terminal and mounted with an auxiliary device, a junction circuit having a first electrical connecting portion provided with a terminal, a second electrical connecting portion provided with a terminal and a base board, and a case in which a connector housing is formed correspondingly to the first electrical connecting portion of the junction circuit, wherein a connector is built up by mounting the first electrical connecting portion of the junction circuit into the connector housing of the case, and wherein the terminal of the base board and the terminal mounted on the second electrical connecting portion of the junction circuit are electrically connected by mounting the base board on the case.

Advantageously, connecting a mating connector having a terminal and the connector, which is provided with the terminal and contained in the case for electrical connection, is effective.

Advantageously, building up a camera module by using a car-mount-type camera for the auxiliary device is effective.

### Effects of the Invention

According to an aspect of this invention, a base board and a connector formed in a case can be electrically connected with a junction circuit and number of components in electrical connecting area can be reduced. Efficiency of operation for connecting the junction circuit with the auxiliary device module is enhanced. The junction circuit can be removed easily from the auxiliary device module so that operations of checking, repairing and recycling for the auxiliary device can be done easily. Reducing number of components in area of electric connecting portion make the auxiliary device module cost down.

According to other aspect of this invention, the structure of the junction circuit can be formed for mounting and removing easily, correspondingly to respective structures of each component of the auxiliary device module. Such junction circuit can be designed to have suitable shape corresponding to respective components for the auxiliary device module so that the junction circuit can be mounted on the auxiliary device module and removed from the auxiliary device module easily in short time when the auxiliary device module is assembled and related components including electric components are disassembled for checking, repairing or recycling.

According to further aspect of this invention, the junction circuit can be mounted easily and securely in short time on a required location in the auxiliary device module.

According to further aspect of this invention, a connector in the auxiliary is built up by mounting the junction circuit having the first and the second electric connecting portions provided with terminals on the case, and the auxiliary device and the connector is connected through the junction circuit by mounting the base board provided with the auxiliary device and terminals on the case. Therefore, the auxiliary device module is good for assembling.

Thus, the auxiliary device module is assembled easily and relationally the auxiliary device module is also disassembled easily so that the structure of the auxiliary device module is good for collecting and recycling to reduce industrial wastes for the earth environmental issue. The auxiliary device module is disassembled and reassembled easily for checking and repairing because the junction circuit can be removed easily from the auxiliary device module. Therefore, auxiliary device modules, which are good for maintenance, can be provided.

During mounting a base board provided with a auxiliary device by prior art on a case, electric wires may be bitten by the base board and the case. It is feared that such auxiliary device may possibly have breaking of wire inside thereof. Therefore, the auxiliary module must be judged as a defective unit.

Abandoning such unfinished products is undesirable for terrestrial environment and wasteful on manufacturing. Then, reassembling such auxiliary device module to replace components related with an electric is required. According to this invention, such defective unit can be eliminated without complicated operation.

According to further aspect of this invention, electrically connecting can be done by mating a mating connector with a connector provided in the case so that a connector, which has a complicated and special structure, is not required. Then, an auxiliary device module, which keeps number of components and low cost, can be provided. Connecting and disconnecting a connector in a case and a mating connector can be done easily in short time, an auxiliary device module, having connectors which can be electrically connected and disconnected easily in short time, is provided.

According to further aspect of this invention, number of components of a camera module can be reduced by applying the auxiliary device module to the camera module. Then, the camera module for a car can be miniaturized, weight-saved and reduced in cost.

When a camera module mounted on a car has a trouble, such as a fault, removing and checking and repairing of the camera module are required. A camera module according to this invention, which can be easily installed and removed, has good maintainability. Since the camera module is disassembled easily, the camera module is easily recycled in case of scrapping and then conforms to an environmental issue by industrial waste.

Although the present invention has been fully described by way of examples with reference to the accompanying drawings, it is to be noted that various change and modifications can be made with the scope of the present invention.

### BRIEF DESCRIPTION OF THE DRAWINGS

FIG. 1 is an exploded perspective view of one embodiment of an auxiliary device module according to the invention;

FIG. 2 is an expanded perspective view of a junction circuit;

FIG. 3 is an expanded perspective view from a bottom side of the junction circuit;

FIG. 4 is a perspective view, showing a condition of the junction circuit mounted on a case;

FIG. 5 is a plan view, showing the condition of the junction circuit mounted on the case;

FIG. 6 is an expanded perspective view of a mating connector;

FIG. 7 is an expanded sectional view of electric wires;

FIG. 8 is a partial expanded view of a wire harness provided with a clamp having O-ring;

FIG. 9 is a perspective view for assembling a camera module by prior art;

FIG. 10 is a perspective view, showing a condition of a malfunction occurred when the camera module by prior art is mounted on the camera case;

FIG. 11 is a conceptual drawing, showing partial expanded sectional views taken along the line R-R of FIG. 9 and FIG. 10 and a connecting area of a wire harness.

### DESCRIPTION OF THE PREFERRED EMBODIMENT

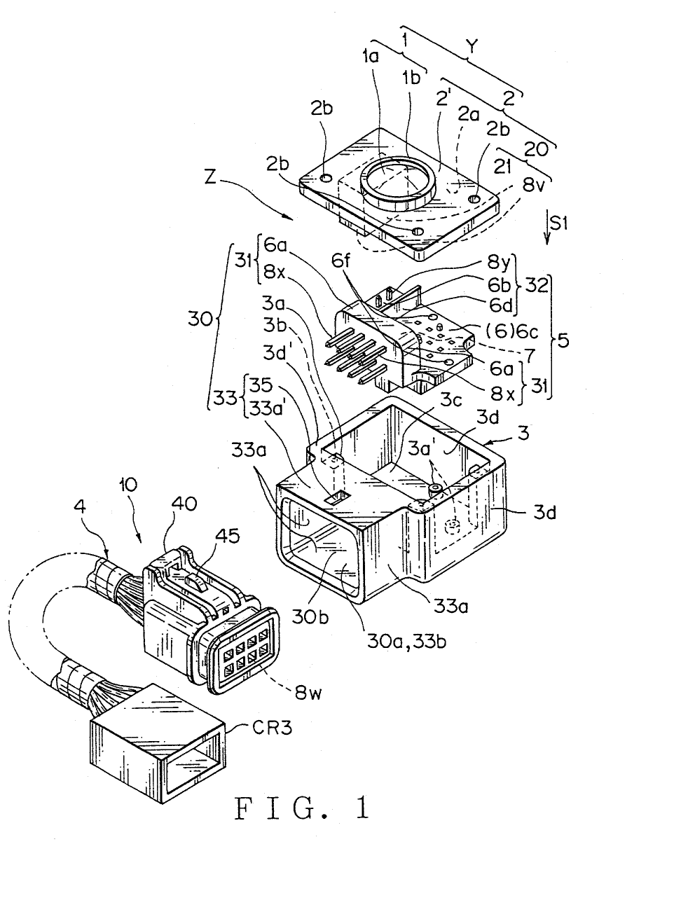

A camera module Z and a connecting board 5 as an embodiment of an auxiliary module Z and a junction circuit 5 mounted on the camera module Z according to this invention will now be described with reference to FIGS. 1-7. The same named elements as respective elements in the example by prior art, mentioned above, are put with the same number and the detailed description on the structure is omitted.

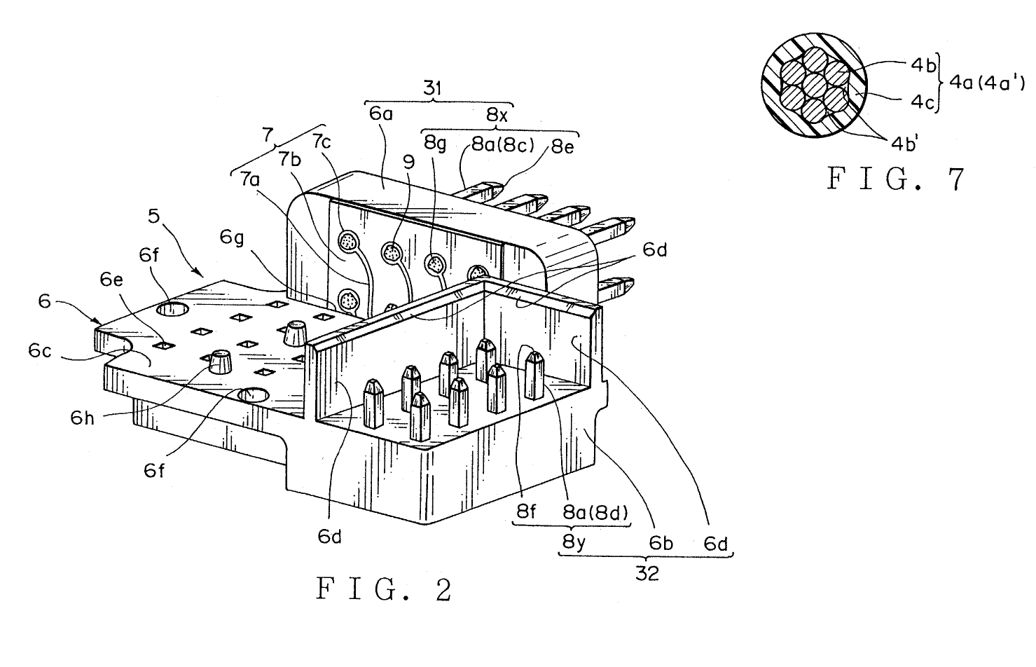

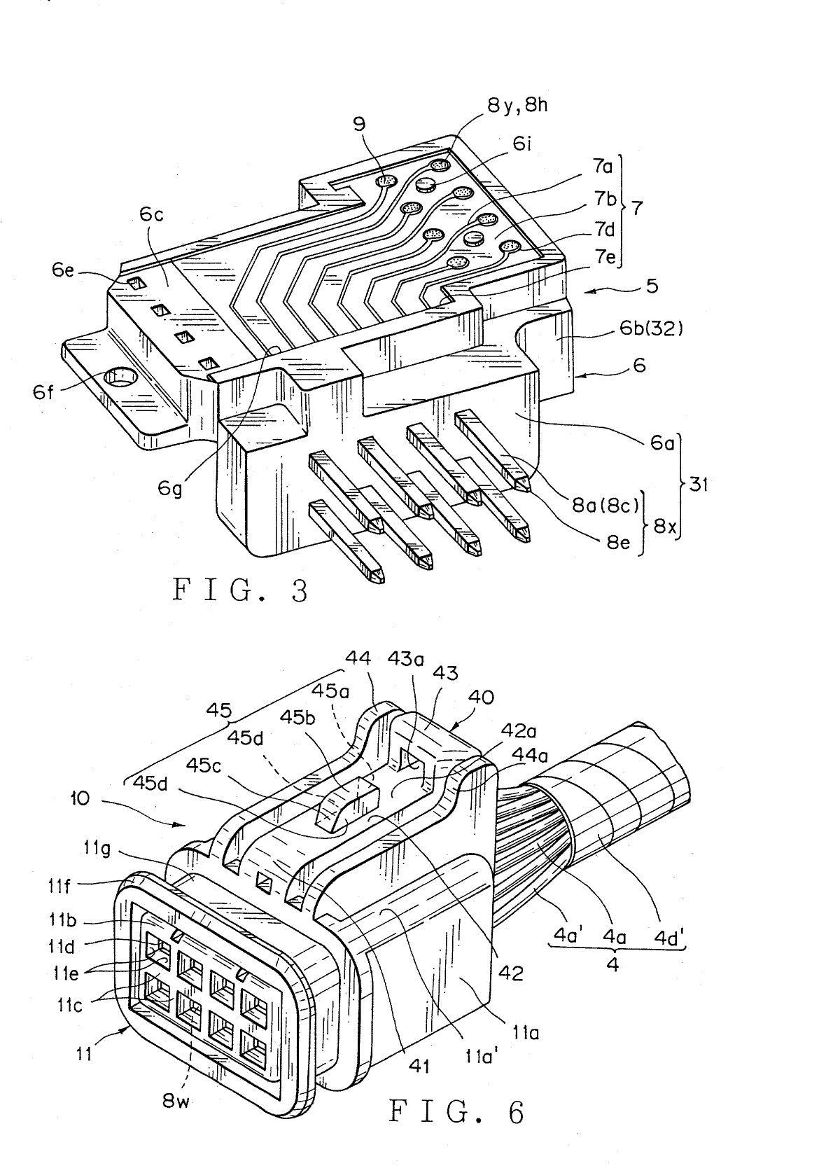

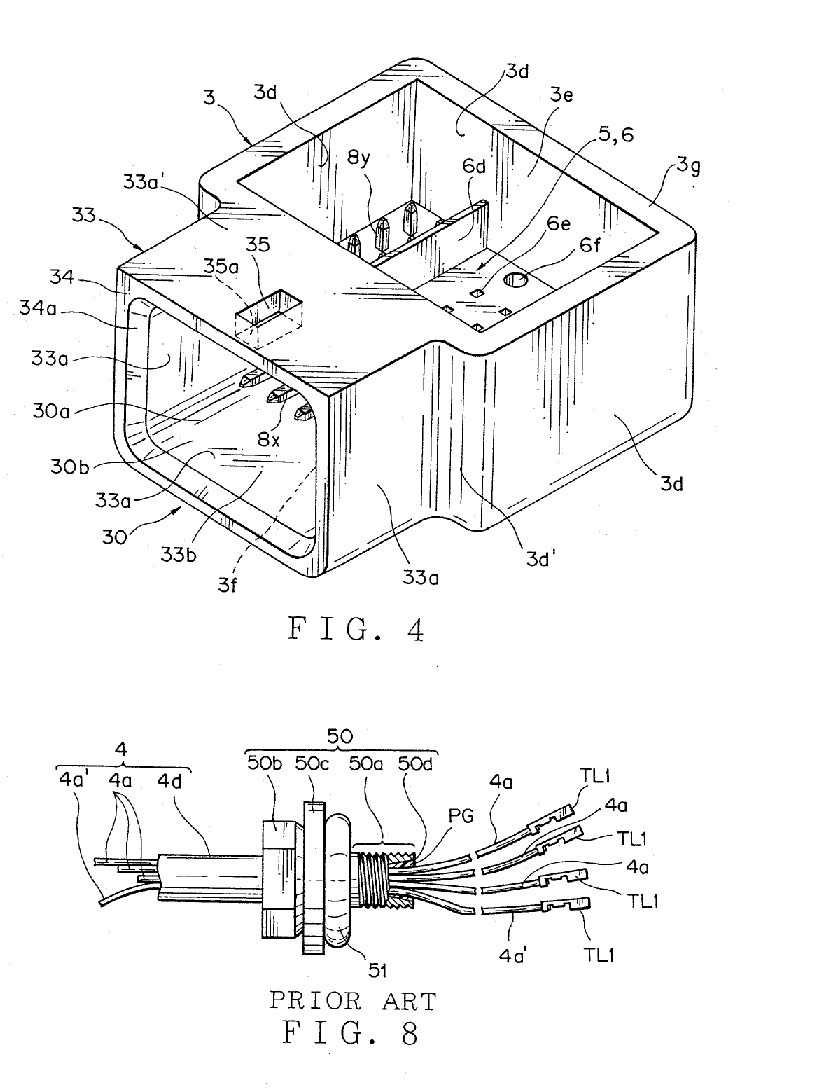

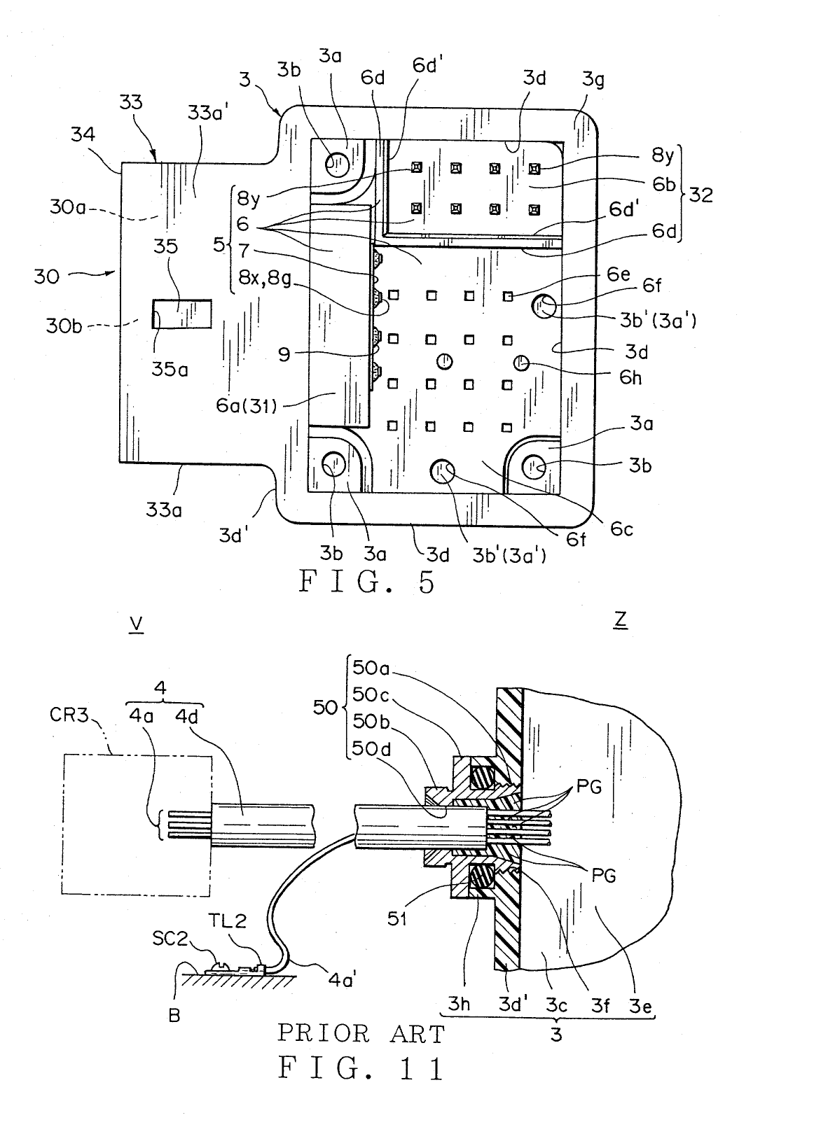

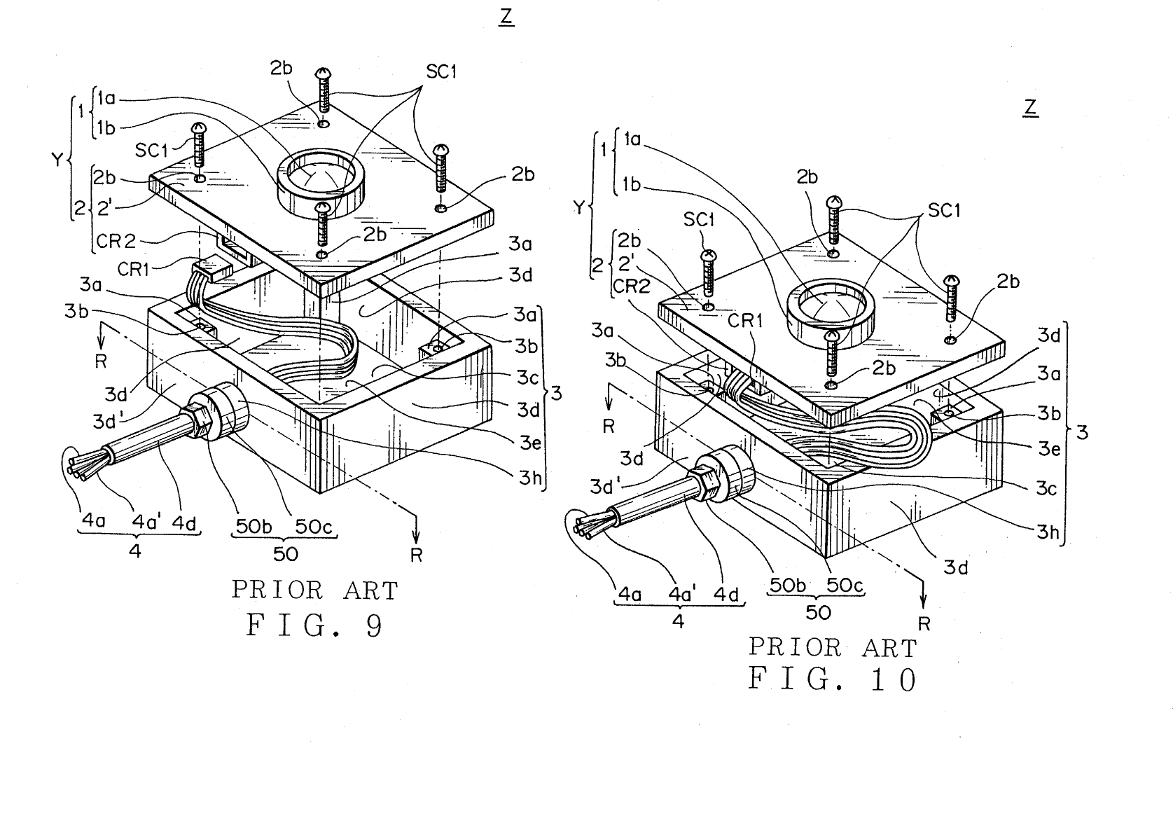

FIG. 1 is an exploded perspective view of a junction circuit and an auxiliary device module according to this invention. FIG. 2 is an expanded perspective view of the junction circuit. FIG. 3 is an expanded perspective view of bottom side of the junction circuit. FIG. 4 is a perspective view, showing a structure of mounting the junction circuit in a case. FIG. 5 is a plan view, showing the structure of mounting the junction circuit in the case. FIG. 6 is an expanded perspective view of a mating connector. FIG. 7 is an expanded sectional view of an electric wire.

Regarding directions of the camera module Z in FIG. 1, a side of a lens 1a in the camera module Z to be assembled is defined as the upper side and a side of a bottom wall 3c in a camera case 3 is defined as the lower side herein. A direction of a wiring harness 4 extending from the camera case 3 is defined as the front side or this side and the opposite direction is defined as the rear side or the back side. Regarding front-side viewing and rear-side viewing, front-side viewing means viewing a connector from connecting side and rear-side viewing means viewing a connector from terminal inserting side, i.e. an electric wire side.

The definition of the directions of upper-lower, front-rear and right-left side is only for explanation and then, the direction is not always corresponding to an actual direction for using the auxiliary device module Z. The auxiliary device module Z may be assembled from any direction. The auxiliary device module Z can be mounted in any direction without departing from the spirit or scope of this invention.

A auxiliary device module Y and the auxiliary device module Z will be described herein. Assembly provided with at least two elements like an auxiliary device 1 such as a camera 1 having a base board 2 is defined as an auxiliary device module Y and physically is called a camera module Y. Assembly provided with at least three elements like an auxiliary device 1 such as a camera 1 and a base board 2 mounted on the auxiliary device 1 such as the camera 1 and the camera case 3, on which such base board 2 is mounted, is defined as an auxiliary device module Z and physically is called a camera module Z. In this invention, the camera modules Y or Z can be called a crowned body.

A connector in this invention is defined as a member provided with electrical connecting elements like a connector housing, a terminal and an electric wire for electrical connecting. A connector according to this invention may be additionally provided with a sealing member like a seal, a packing or a rubber plug for enhancing water-tightness or also provided with a rear holder as an optional component.

An electric wire 4 in this invention gives a generic name to an insulating cover 4c, a conductive wire 4b coated with enamel or other coating material or a conductive wire 4b without coating. Describing the cable 4a or 4a′ in this invention, the cable 4a or 4a′ is called a core wire and is formed with a conductive wire 4b coated with an insulating cover 4c or enamel or with a plurality of the conductive wires 4b coated with an insulating cover 4c or enamel as shown in FIG. 7.

A CCD camera or MOS (Metal Oxide Semiconductor) camera or any kind of camera can be used for a camera in this invention.

Respective components structuring the camera module Y, Z will be described in detail herein. The camera 1 is provided with a lens 1a and other members including a lens area portion 1b, and mounted with a CCD as shown in FIG. 1.

Regarding the base board 2, the base board body 2′ is formed into a rectangular solid shape, as shown in FIG. 1. The base board body made of insulating resin is provided with a plurality of printed wire (not shown) of metallic foil such as copper foil to form a printed circuit board (PCB for short) . An insulation coating is provided on the printed circuit board including the printed wire for preventing electrical malfunction such as electrical leak or short circuit. Thus, the base board 2 is formed and may be called as a printed circuit board.

Respective electrical components (not shown) such as a relay, an electric fuse, a capacitor, a semiconductor, a terminal, a bus bar, a connector or an electric wire to be connected with an electric wiring is mounted on the base board body 2′. The base board 2 is a plate which supports such electrical components and insulate between each electrical component to prevent electrical short circuit. Then, the base board can be called an insulating board.

The base board 2 is provided on the bottom surface 2a with a connector 20 having a female terminal 8v and a connector housing 21. One end of the female terminal 8v which is received in a receiving section of the connector housing 21 of the PCB connector 20 is joined electrically by soldering with the electric wiring which is formed by means of metallic foil such as copper foil provided on the base board 2. The connector 20 on the printed circuit board is connected with a second connector body 32 of a junction circuit 5, shown in FIGS. 1-5.

A mounting hole 2b is provided respectively at total three positions in the vicinity of each of four corners of the base board 2 to be fixed on the camera case 3. Fastenings such as three screws (not shown) are inserted into the mounting holes 2b provided on the base board 2 and screwed by a fastening device such as a screw driver or a wrench so that the base board, i.e. the camera module Y, is mounted on the camera case 3. The base board 2 shown in FIG. 1 works as a cover. However, a separated cover from the base board 2 can be effective and any type or shape of the base board 2 and the cover can be used without departing from the spirit or scope of this invention.

Describing a material of a molding portion 6 to form the base board 2 or a junction circuit 5, i.e. a connecting board 5, synthetic resin such as thermosetting resin or thermoplastic resin is preferable for good formability and good performance to insulate various electric components such as bus bars or terminals. Any above synthetic resin with low water absorbing property is preferable on dimensional stability, volume productivity and stable electric performance.

Thermoplastic resin to be used for the molding portion 6 structured the connecting board 5 is preferable for shorter molding time. A hot-melt material is preferably selected as the thermoplastic resin. The hot-melt material is a kind of adhesives to be soften or melted by heating andto anchor rapidly by cooling.

The hot-melt material has such characteristics and then molding with the hot-melt material can perform shorter molding time to enhance productivity for the molding portion. The hot-melt material is an adhesive by using a thermoplastic resin as a substrate.

Ethylene-vinyl acetate copolymer (EVA for short), ethylene-ethyl acrylate copolymer (EEA for short), polyamide (PA for short), polyurethane (PUR for short), polyethylene (PE for short), polyester or atactic polypropylene can be used for a substrate polymer of a hot-melt material.

A reaction type hot-melt material by PUR as a substrate to be enhanced on heating resistance or a tack type hot-melt material instead of solvent type adhesive can be used. Furthermore, an aqueous hot-melt material is thought for environmental issue and saving materials. A hot-melt material by polyamide substrate is preferable to be superior totally on productivity and cost.

An electric contact portion of a male terminal is inserted into a female terminal to be connected electrically. An electric contact portion of a bus bar having a tab is inserted into a female terminal to be connectedelectrically as a male terminal. Shapes of male terminals are rectangular, round and tab. Shape of the male terminals in this invention may be applied by round or flat plate other than rectangular.

Rectangular male terminals 8x, 8y, as shown in FIGS. 1-5, and an example of its manufacturing method will be described herein. Ametallic terminal material is cut into a predetermined shape. Terminal bodies 8c and 8d, front ends 8e and 8f, and rear ends 8g and 7h are formed in the cut material by press forming and bending. The metallic material may be wiped to improve accuracy of electric contact portions 8a, 8b or respective area including thereof of the male terminals 8x, 8y.

An example of manufacturing method is to set a long metallic terminal material at an input portion of a press machine and to press the material by transferring it for each pressing step in sequence. The steppes may be cutting of the metallic terminal material, bending and press forming by pressing dies, such as a hammer and anvil. Required final shapes of male terminals 8x, 8y or a bus bar having a male terminal may be formed at output portion of the press machine. Thus, the male terminals 8x, 8y having respective required shape can be manufactured efficiently in shorter time.

This manufacturing method for the male terminals 8x, 8y and similar components having a male terminal can be applied to the female terminal 8v of the connector 20, which is mounted on the bottom surface 2a of the base board 2 shown in FIG. 1, or a female terminal 8w which is received in a receiving section of a mating connector 10 shown in FIGS. 1 or 6.

A front end 8e of the male terminal 8x is formed into taper to the front end, as shown in FIGS. 2-4, to insert easily the male terminal 8x, which is provided in a connector 30 of the camera case 3 shown in FIG. 4, into a terminal receiving section of the mating connector 10 through a terminal inserting opening 11d of a connector housing 11 shown in FIG. 6 when the mating connector 10 is connected with the connector 30 formed in the camera case 3.

A front end 8f of the other male terminal 8y is also formed into taper to the front end as shown in FIGS. 2 and 4.

Bronze, brass, copper alloy or aluminum alloy can be used for a terminal material of a male terminal 8x or 8y, a female terminal 8v or 8w, or a bus bar. Any kind of conductive materials, such as a metal, enduring heating by soldering can be used for male terminals 8x, 8y or female terminals 8v, 8w in this invention.

Protective surface finishing, such as metal plating, can be applied to terminals made of above materials for improving its corrosion resistance. Such surface finishing may be eliminated preferably on cost, if the terminals can perform sufficiently under a normal use condition.

The bus bar is a branch circuit made of a conductive metal plate and is. formed with a plurality of electrical contact pieces. Provided bus bars are a bus bar body, a bus bar for connectors, a bus bar for relay, a bus bar for fuse, a bus bar for power supply or the like. The bus bar for fuse is called a clamp hold type terminal or a tuning fork shape terminal by the formed shape. The bus bars may be provided with a relay terminal, such as an F-F terminal if required.

The F-F terminal is a terminal having a female connecting portion at the both end of the terminal and called a F-F terminal for a fuse to be used for connecting a bus bar and a fuse and a F-F terminal for a relay to be used for connecting a bus bar and a relay.

A bus bar, which a body and a tab to be a terminal are formed by press working, is preferable on cost saving because of keeping number of components. The tab provided in the vicinity of the edge area of the bus bar may perform as a terminal.

The female terminal 8v of the PCB connector 20 is joined at a predetermined position with the electric wiring made of metal foil, such as copper foil, provided on the base board body 2′ of the base board 2 to be soldered integrally. Thus, the PCB connector 20 structures a part of the base board 2.

A connector which is joined with a metal foil electric wiring provided on a printed circuit board, such as a base board 2 or a flexible printed circuit board 7, by soldering is called a PCB connector. PCB is an abbreviation of a printed circuit board. A rectangular pin type terminal or bus bar is generally used for the PCB connector. However, any pin type terminals can be used for the connector in this invention.

The PCB connector has generally two mount types of vertical mount type and horizontal mount type. The vertical mount type PCB connector is mounted so that the connecting direction of the male and female connectors is vertical for the base board. The horizontal mount type connector is mounted so that the connecting direction of the male and female connectors is horizontal for the base board.

The camera case 3, as shown in FIGS. 1, 4 and 5, is formed with a bottom wall 3c and side walls 3d, 3d′ standing around the bottom. wall to provide a receiving section 3e. The camera case 3 is provided, at three positions in the receiving section 3e, with mount portions 3a and tapped holes 3b correspondingly to three mounting holes 2b of four corners of the base board 2 of the camera module Y shown in FIG. 5 to fix the camera module Y on the camera case.

To mount the base board 2, working as a cover too, on the camera case 3, each electrical component provided on the bottom surface of the camera module Y is protected from the outside. The camera case 3, as shown in FIG. 4 and 5, is provided on a top end surface thereof with a touching surface 3g, which is formed into uniform flat correspondingly to a touching uniform flat surface provided on the bottom surface 2a in the vicinity of four side edges of the base board 2.

Sealing of the electric components in the camera module Z shown in FIG. 1 by the camera case 3 and the base board 2 working as a cover is described herein. To mount the base board 2 working as a cover, i.e. the camera module Y, on the camera case 3, the touching surface 3g of the camera case 3 abuts on the touching surface of the base board 2 and then, the electric components are sealed in the receiving section 3e of the camera case 3.

Thus, the camera 1 is sealed securely by the camera case 3 and the base board 2 working as a cover. Therefore, infiltration of water or dust into the camera module Z form the outside is prevented and malfunction of the camera module Z can be prevented thereby.

Preferably, sealing material, such as a seal, a packing or adhesive, may be placed between two abutted touching surfaces to eliminate gaps therebetween for enhancing sealing effect to seal securely between the camera case 3 and the base board 2 working as a cover.

The camera case 3 is provided, from the receiving section 3e to the outside of the camera case 3 with a throughhole 3f continuously to an opening 30b of a connector housing 33 through a connector opening 30a, as shown in FIGS. 1, 4 and 5.

A housing means generally a box shaped portion for receiving a component, a box for placing a frame to put a device therein or a box-like member. A connector housing 33 is provided with four side walls 33a, 33a′ to form a mating connector receiving section 33b which is rectangular box shaped in view from the electric wire 4, as shown in FIGS. 1, 4 and 5.

The connector housing 33 is provided, around the insertion opening 30b, with a taper guide surface 34a for inserting easily the mating connector 10 into the mating connector receiving section 33b of the connector 30 in the camera case 3 when the mating connector 10 shown in FIGS. 1-6 is inserted into the connector 30 of the camera case 3 shown in FIGS. 1-4.

A sliding contact surface 45b of a locking projection 45, which is provided on a rocking arm 40 of the mating connector 10, contacts glidingly with a sliding surface of inside of the top wall 33a′ in the connector housing 33 while the mating connector 10 is inserted into the connector 30 of the camera module.

The connector housing 33 is provided as shown in FIGS. 1, 4 and 5, on the top wall 33a′, with an engaging portion 35, physically looking, engaging opening 35 to engage with the locking projection 45 of the locking arm mounted on the mating connector 10, shown in FIGS. 1-6.

The engaging opening 35, which is provided on the top wall 33a′ of the connector housing 33, is formed by an engaging surface 35a formed close to side of the insertion opening 30b of the connector housing 33, a side wall facing the engaging surface 35a in parallel and two side walls standing vertically on the engaging surface 35a continuously to the side wall. Thus, the engaging opening 35 is a rectangular throughhole corresponding to the locking projection 45 of the mating connector 10.

The engaging surface 35a of the engaging opening 35 provided in the connector housing 33 is formed perpendicularly to an inner surface, including the sliding surface, of the top wall 33a′ of the connector housing 33, as shown in FIGS. 1, 4 and 5. The engaging surface 35a of the engaging opening 35 provided in the connector 33 shown in FIGS. 1, 4 and 5, corresponds to the locking surface 45a of the locking projection 45 provided on the locking arm 40 of the mating connector 10, as shown in FIGS. 1-6.

The connector housing 33 is formed integrally to the camera case 3 with the same material by injection molding. Then, number of the parts can be kept. Thereby, double molding or over-molding which is a complicated manufacturing method and increases a cost of the auxiliary device module Z, such as the camera module Z, is not required for the connector housing.

Manufacturing the camera case 3 or a protecting cover for the camera 1 with aluminum alloy by die casting is preferable on a light weight, mechanical strength, corrosion resistance, workability and productivity.

The CCD camera mounted on the outside of a car is exposed to weather. Therefore, using the corrosion resistant material is important and using a small specific gravity material is preferable for weight saving. An aluminum alloy or a synthetic resin, which can be injection molded and is thermoplastic, for the camera case 3 or a cover of the camera 1 is preferable regarding good mass-productivity.

The wiring harness 4, as shown in FIGS. 1-6, is mounted extending to this side into an electric wire side opening of the connector housing 11 of the meting connector 10 to connect and thereby the wiring harness 4 and the mating connector 10 are connected. The cables 4a, 4a′ to be connected electrically are integrally bundled by means of a bundling tape 4d′ or a flexible waterproof tube to assemble the wiring harness 4.

Generally, a wiring harness means a bundles electric wiring of an electric circuit in a car other than a high voltage electric circuit and a starting circuit.However, awiring harness herein is not limited by above meaning. A wiring harness herein is defined an electric wiring assembly in which wiring components including an electric wire are integrated in preprocess by electric wire manufactures correspondingly to a model, type or grade of a car to be mounted easily in a car assembling line. Electric wiring for a car is mostly integrated as a harness.

An inside car electric wiring for starting, battery charging or lighting is called a low voltage cable and an electric wiring for an ignition system of a car is called a high voltage cable. A crosslinked polyethylene coating heat-resistant electric wire or a crosslinked vinyl coating heat-resistant electric wire is used for a low voltage cable. Chloroprene rubber, which is good sheathing, oil and ozone resistant, is used for rubber insulation of ahigh voltage cable. These electric wires may be kept under vibration, high or low temperature, machine oil or weather, depending on positions to be used. Car components including car electric wires are required to keep stable performances under hard conditions as mentioned above.

The cables 4a, 4a′, structuring the wiring harness 4, are formed into core wires having conductive wires 4b and insulation cover 4c. Small gap 4b′ exists between respective conductive wires 4b. The wiring harness, formed with bundled such cables 4a, 4a′, are bent at a required position thereof when the wiring harness is mounted on a car.

Good conductive and flexible material to endure repeated bending, for example a copper alloy wire such as a soft copper wire, is suitable for the conductive wire 4b. The cables 4a, 4a′ are formed by bundling a plurality of conductive wires 4b and twisting simultaneously to have a durable core wire. An enamel coating conductive wire 4b which keeps a diameter and has higher insulating performance may be used for cables 4a, 4a′ or the wiring harness 4.

An insulating and durable material for repeated bending is preferable for the insulating cover 4c or the tube for protecting the conductive wires 4b. A flexible insulating material is expected for the cover or the tube. Thermoplastic resin, such as vinyl chloride polymer or polyethylene polymer, or rubber or combined material thereof can be used for them. Any kind of a filler can be added into the insulating material, if required. When the insulating material, mentioned above, is formed by extruding, the conductive wire, such as a copper wire, is inserted at an extruding die head to combine the insulating cover 4c and the conductive wire 4b. Thus, the cables 4a, 4a′ or the wiring harness 4 is formed.

The wiring harness 4 is bent at a required position to fit a car shape and mounted on the car. Thus, respective components and devices in the car are electrically connected. Not only the cable 4a and the drain wire 4a′, but also a dummy wire may be assembled in the wiring harness 4 to connect with other electric circuit.

An electric component and the camera module Z are connected electrically through non-waterproof connector CR3 (FIG. 1) in the car, by the wiring harness 4. The drain wire 4a′ is brunched at middle point of the wiring harness 4 (FIG. 11) and a terminal TL2, which is joined with end of the drain wire 4a′, is fixed to a frame of a car body B with a screw SC2. Thus, fixing the drain wire 4a′ to the car body, the drain wire 4a′ performs a ground to be connected electrically to the car body.

A circuit body by a flat cable, by a ribbon cable of round wires, by a flexible printed circuit (FPC for short) or by a flexible flat circuit (FFC for short) may be used for the wiring harness.

The flexible printed circuit (FPC) body 7, as shown in FIGS. 2 and 3, is a flexible printed circuit board which is provided, on an insulating sheet 7b, with a plurality of printed wire 7a made of metal foil, such as copper foil, byprinting. The printed wire 7a of the flexible printed circuit body 7. is protected by the insulating sheet 7b and a protecting layer on the insulating sheet 7b to prevent short circuit by contacting the printed wire 7a of the flexible printed circuit body 7 and other member.

The flexible flat circuit (FFC) body is formed juxtapositionaly, on an insulating sheet, with a plurality of printed wires such as thin straps, fine single threads or an enamel coating wire. Thus, the wiring harness may be applied by bundling of cables or core wires, or parallel wires.

The wiring harness may be formed not only with a plurality of the cables 4a, 4a′, as shown in FIGS. 1 and 6, but also with electric wires and optical fibers, or bundled optical fibers. Furthermore, a grommet or other optional parts may be added on a wiring harness, if required.

An embodiment according to this invention will now be described with reference to FIGS. 1-7.

A plastic portion 6 of a connecting board 5, shown in FIGS. 1-3, is formed integrally with a first base portion 6, a second base portion 6b and base portion 6c by injection molding. The plastic portion 6 is injection-molded easily and in short time with a hot-melt material of polyamide resign.

The plastic portion 6 of the connectingboard 5 is provided, in the vicinity of the surroundings of the second base portion 6b, with a L-shape partition wall 6d, as shown in FIGS. 2-5. The partition wall 6d, i.e. a side wall 6d, works as a connector housing. The L-shape side wall 6d is provided, at the inside corner of a top end thereof, with a taper guide surface 6d′, as shown in FIGS. 2 and 5, to connect easily a connector 20 provided in the camera module Y and a second electric connecting portion 32 of the connecting board 5.

Therefore, the second electric connecting portion 32, which is provided with the second base portion 6b, the L-shape side wall 6d, i.e. a connector housing, and a male terminal 8y, can be defined a connector.

The first electric connecting portion 31, i.e. the first connector body 31, is structured by press-fitting eight male terminals 8x into eight terminal receiving holes which are provided in the first base portion 6a of the plastic portion 6. The second electric connecting portion 32, i.e. the second connector body 32, is also structured by press-fitting eight male terminals 8y into eight terminal receiving holes which are provided in the second base portion 6b of the plastic portion 6. The male terminals 8x of the first electric connecting portion 31 and the male terminals 8y of the second electric connecting portion 32 are electrically connected by the printed wire 7a of the flexible printed circuit board 7.

Connection between the male terminals 8x or 8y and the printed wire 7a of the flexible printed circuit board 7 is described herein in detail.

A rear end 8g of the male terminal 8x, which is provided in the first connector body 31 of the connecting board 5, is joined electrically by soldering with one end 7c of the printed wire 7a, which is provided in the flexible printed circuit board 7, through a solder material 9, as shown in FIGS. 2 and 5.

A rear end 8h of the male terminal 8y, which is provided in the second connector body 32, is joined electrically by soldering with other end 7d of the printed wire 7a, which is provided in the flexible printed circuit board 7 through a solder material 9, as shown in FIG. 3.

A throughhole for inserting the rear end 8g of the male terminal 8x or the rear end 8h of the male terminal 8y therethrough is provided at respective ends 7c, 7d of the printed wire 7a formed on the flexible printed circuit board 7. After the rear ends 8g, 8h, i.e. soldering area 8g, 8h, of the male terminals 8x, 8y are inserted into the throughholes, the rear ends 8g, 8h of the male terminals 8x, 8y is joined by soldering with the ends 7c, 7d of the printed wire 7a on the flexible printed circuit board 7 to be connected electrically and fixed mechanically. Thus, the junction circuit 5, i.e. the connecting board 5, is built up.

The base board 2 having the camera 1 and the connector 30 formed in the camera case 3 can be electrically connected with the connecting board 5. Therefore, number of peripheral components of electrical connection can be reduced and assembling operation and productivity for mounting the connecting board 5 into the camera module Z are enhanced.

Furthermore, the connecting board 5 can be easily removed from the camera module Z and then, operations of checking, repairing and recycling for the camera module Z can be easier. Cost of the camera module Z can be reduced by smaller number of electrical connecting components.

The flexible printed circuit board 7, as shown in FIG. 2 and 3, is structured by providing the printed wire 7a made of a flexible material on the insulating sheet 7b made of a flexible material and covering a transparent or translucent flexible protection sheet on the printed wire and the insulation sheet.

The flexible printed circuit board 7 is formed into L-shape by bending in a plane. One end and other end of the L-shape flexible printed circuit board 7 are electrically connected by eight printed wires 7a. Forming the flexible printed circuit board 7 into L-shape, the male terminal 8x can be provided perpendicularly to the male terminal 8y.

The plastic portion6 is provided with an inserting opening 6g for inserting the flexible printed circuit board 7 therethrough and the flexible printed circuit board 7 is inserted through the inserting opening 6g. The flexible printed circuit board 7 is bent rectangularly at inside of the inserting opening 6g or in the vicinity of the inserting opening 6g of the plastic portion 6 to form a bending portion 7e of the flexible printed circuit board 7 (FIG. 3). Thus, the flexible printed circuit board connects the first connecting portion 31 and the second connecting portion 32.

Thereby, the connecting board 5 can be formed correspondingly to respective components, such as the camera case 3, which structures the camera module Z. Therefore, the connecting board 5, which is formed correspondingly to shapes of a mounting components, such as the camera case 3, can be mounted and removed easily.

The connecting board 5 can be designed to have suitable shape corresponding to respective mounting components, such as the camera case 3 in the camera module Z so that the connecting board 5 can be removed easily in short time when related components including electric components are disassembled for checking, repairing or recycling and can be mounted easily in short time on the camera module Z.

The flexible printed circuit board 7 is provided with a positioning hole and the plastic portion 6 is provided with a positioning projection 6i corresponding to the positioning hole, as shown in FIG. 3. The flexible printed circuit board 7 is mounted on the plastic portion 6 to insert the positioning projection 6i of the plastic portion 6 into the positioning hole of the flexible printed circuit board 7.

The connecting board 5 is provided with two board mounting holes 6f correspondingly to the tapped holes 3b′ of two mounting portions 3a′ formed on a bottom wall 3c of the camera case 3, as shown in FIGS. 1-5, to mount easily the connecting board 5 in the receiving section 3e of the camera case 3. Therefore, the connecting board 5 can be mounted easily in the receiving section 3e of the camera case 3, securely in short time.

The connecting board 5, shown in FIGS. 2 and 5, is also provided, on the base board 6c, with two positioning projections 6h for mounting easily. other component on the base board 6c of the connecting board 5.

The positioning projection 6h shown in FIG. 2, provided on the base board 6c of the connecting board 5, is formed into taper to the top from the base, i.e. conical shape. The positioning projection 6h having such shape is preferable to fit easily into a mounting hole on the other component.

The connecting board 5 is provided, on the base board 6c, with a terminal receiving hole 6e for inserting other terminal or a component, as shown in FIGS. 2-5.

The base board 2, on which the camera 1 and the PCB connector 20 having the female terminal 8v are mounted as shown in FIG. 1, i.e. the camera module Y, is set to be mounted on the camera case 3 along a mounting direction S1.

The connecting board 5 is provided with the first connecting portion 31 formed by mounting the male terminal 8x on the first base board 6a, the second connecting portion 32 formed by mounting the male terminal 8y on the second base board 6b, and the base board 6c. In the connecting board 5, the male terminal 8x of the first connecting portion 31 and the male terminal 8y of the second connecting portion 32 are electrically connected by the printed wires 7a of the flexible printed circuit board 7.

The connecting board 5 is set as same as the camera module Y to be mounted on the camera case 3 along a mounting direction S1.

The camera case 3, as shown in FIGS. 1, 4 and 5, is formed with a connector housing 33 correspondingly to the first connecting portion 31 of the connecting board 5 shown in FIGS. 1-3. When the connecting board 5 is mounted in the receiving section 3e of the camera case 3, the first connecting portion 31 of the connecting board 5 is received into the connector housing 33 of the camera case 3 to build up a connector 30 in the camera case 3.

Thereafter, mounting the base board 2, i.e. the camera module Y, on above camera case 3, the female terminal 8v of the PCB connector 20, soldered with the base board 2, and the male terminal 8y of the second connecting portion 32 of the connecting board 5 are connected. Thus, the camera module Z is assembled.

The connector 30 in the camera module Z is built up by mounting the connecting board 5, having the first and the second connecting portions 31, 32 provided with the male terminals 8x, 8y, in the receiving section 3e of the camera case 3, and the camera 1 is connected with the connector 30 through the connecting board 5 by mounting the base board 2 having the camera 1 and the PCB connector 20 with the female terminal 8v on the camera case 3. Therefore, the camera module Z has good productivity for assembling.

The auxiliary device 1, such as the camera 1, and electric wiring are isolated units and then, respective components to be mounted on the camera case 3 can be assembled in separated process, differed from electric wiring so that productivity for assembling is improved. Complicated assembling operation in case of a product by prior art is not required and then, the assembling of the camera module Z can be operated in short time. The camera module Z is assembled with the connecting board 5 having the male terminals 8x, 8y so that the connector 30 can be built up easily in the camera module Z in assembling process. Therefore, the connecting board 5 may be designed to automate the assembling operation of the camera module Z.

The camera module Z is also easy to be disassembled and then, the structure is good to collect the camera module Z for recycling. Thus, the camera module Z contributes to reduce industrial waste for environmental protection. The connecting board 5 can be removed easily from the camera module Z so that checking, repairing, disassembling and reassembling for the camera module Z can be operated easily. Therefore, the camera module Z having good maintainability can be provided.

Defective unit, shown in FIG. 10, occurred during assembling a camera module Z by prior art can be eliminated. During mounting a base board 2 having a camera 1 by prior art on a camera case 3, it is feared that a cable 4a and a drain wire 4a′ are bitten by the base board 2 and the camera case 3. The cable 4a or the drain wire 4a′, which are bitten by a gap, may possibly have breaking of wire inside thereof. Therefore, a camera module Z with such bitten cable 4a or drain wire 4a′ is judged as a defective unit.

Abandoning such unfinished products is undesirable for terrestrial environment and wasteful on manufacturing. Then, reassembling such camera module Z to replace components related with a cable 4a, a drain wire 4a′, a wiring harness 4 with a tube 4d and a clamp 50 is required. According to this invention, such defective unit can be eliminated without above complicated operation.

The mating connector 10, which is connected with the connector 30 in the camera module Z, will be described with reference to FIGS. 1 and 6. The mating connector 10 is provided with a box-type connector housing 11 formed by a side wall 11a, a top wall 11a′ and a front wall 11b, a receiving section thereof and a female terminal 8w received into the receiving section in the connector housing 11.

The connector housing 11, structuring the mating connector 10, is provided, at surround area of the end of the front wall 11b, with a taper guide surface 11f, as shown in FIG. 6, to insert easily the mating connector 10, shown in FIG. 6, into the mating connector receiving section 33b of the connector 30 in the camera case 3, shown in FIG. 4, when the mating connector 10 is inserted into the connector 30 for connecting.

The connector housing 11 of the mating connector 10 is provided, in the front wall 11b thereof, with eight terminal inserting openings 11d to connect electrically the eight female terminals 8w, received in respective receiving sections of the connector housing 11 of the mating connector 10, with eight male terminals 8x of the connector 30 in the camera module Z. The connector housing 11 of the mating connector 10 is also provided, in the front wall 11b thereof, with vertical partitioning walls 11c and horizontal partitioning walls 11c.

The connector housing 11, structuring the mating connector 10, is provided, at an open end of the terminal inserting opening 11d, with a taper guide surface 11e, as shown in FIG. 6, to insert easily the male terminal 8x provided in the connector 30 of the camera case 3, shown in FIG. 4, into the terminal receiving section of the connector housing 11 of the mating connector 10, shown in FIG. 6, when the mating connector 10 is inserted into the connector 30 for connecting.

The connector housing 11 of the mating connector 10 is provided, between the front wall 11b and a foot portion 41 of the locking arm 40, with a groove 11g. Preferably, an annular rubber O-ring may be placed in the groove 11g. The connector housing 11, structuring the mating connector 10, is provided, at the opposite side of the terminal inserting opening 11d, with an electric wire inserting opening to pass the electric wire, such as the cables 4a, 4a′ or the wire harness 4, therethrough. The electric wire inserting opening may be preferably provided with a rubber plug having a sealing hole for inserting an electric wire therethrough and formed correspondingly to the inner shape of the connector housing 11 of the mating connector 10.

The connector housing 33 in the camera case 3, shown in FIGS. 1 and 4, may be preferably provided, at a rear area of the mating connector receiving section 33b, with an annular rubber plug formed correspondingly to the inner shape of the connector housing 33.

Thereby, the mating connector 10 and the connector 30 in the camera case 3 may be waterproofed to protect respective electric devices from infiltration of water or dust into inside of the camera case 3 or camera 1 for preventing malfunction of the camera module Z caused by water or dust.

Standard mating connector for general purpose or non-waterproof mating connector can be used also.

The electric wires, such as cables 4a, 4a′, are inserted through the electric wire inserting openings which are formed at opposite side of the terminal inserting opening 11d of the connector housing 11 structuring the mating connector 10. The cables 4a and drain wire 4a′, shown in FIG. 7, are extended from a winding end of a tape 4d′ of the wire harness 4 into inside of the connector housing 11 of the mating connector 10.

A part of the conductive wire 4b is exposed in the connector housing 11 of the mating connector 10 by peeling the insulating cover 4c at the end of the cable 4a or the drain wire 4a′. The conductive wires 4b and the insulating cover 4c of the cable 4a and the drain wire 4a′ are joined to each electric wire connecting portion, i.e. a conductive wire crimp piece and a cover clamping piece, of respective female terminals by a special tool. Thus, the electric wire connecting portions of the female terminals 8w are fixed and electrically connected with the cable 4a and the drain wire 4a′. Preferably, the wire harness 4 may be bundled by a waterproof tube. Any type of a wire harness can be used in this invention.

The female terminals 8w, which are joined to the cables 4a, 4a′ of the wire harness 4, are inserted into the receiving sections of the connector 10 and fixed securely by lance-shape locking pieces provided in the terminal receiving sections of the connector 10. The locking piece may be not only lance-shape but also arm-shape or other shape.

A crimp contact type terminal, which may be connected with the cables 4a, 4a′, is described herein. A crimp contact type terminal is provided with a barrel portion, plastic deformed by a crimping tool to connect with an electric wire mechanically and electrically. Generally, the terminal includes a wire barrel, i.e. a conductive wire crimp piece, for crimp contacting with a conductive wire at insulation cover removed area, and an insulation barrel, i.e. a cover clamping piece, for crimp contacting with an insulation cover area of an electric wire. The wire barrel is classified into a closed barrel and an open barrel.

A female terminal is a mating terminal corresponding to a male terminal to receive the male terminal therein for electrically connecting. Some female terminals have an elastic contact piece, such as a spring, for generating a contact force. The female terminals 8v, 8w in an embodiment of the invention are rectangular box-shape, corresponding to rectangular pin type male terminals 8x, 8y, female terminals having an elastic contact piece. A rectangular or cylindrical tube type female terminal corresponding to a flat tab type or round pin type male terminal or other type female terminal can be used in this invention.

As shown in FIG. 1, the mating connector 10, which is provided in the connector housing 11 with the female terminals 8w connected with the wire harness 4, and the connector 30, which is provided with the male terminals 8x and formed in the camera case 3, are mated so that the both connectors are electrically connected.

Thus, electrical connecting can be done by mating the connector 30 in the camera case 3 and the mating connector 10 joined to the wire harness 4. Therefore, a connector 30 or a mating connector 10 having complicated structure is not required. The camera module Z, which cost is reduced with keeping number of parts, can be provided.

Connecting or disconnecting of the connector 30 in the camera 3 and the mating connector 10 of the wire harness 4 can be done easily in short time. Therefore, a camera module Z, in which electrical connecting and disconnecting of mated connectors can be done easily in short time, is provided.

A standard connector for general purpose can be used for the mating connector 10 connected with the auxiliary device module Z, such as the camera module Z, so that standardizing of parts, reducing management operation thereby and reducing cost can be done.

A locking arm 11a′, as shown in FIGS. 1 and 6, is formed integrally to the top wall 11a′ with the same resin material of the mating connector 10 on the top wall 11a′ of the connector housing 11, made of a resin, structuring the mating connector 10. The locking arm 40 is formed with a foot portion 41, an arm 42 and an operating portion 43. A reference surface 42a of the arm 42 is formed in parallel to an outside surface of the top wall 11a′ on which the locking arm 40 is provided.

A pair of projecting portions 44, as shown in FIGS. 1 and 6, are provided symmetrically in center of the locking arm 40 on the top wall 11a′ of the connector housing 11 of the mating connector 10. The pair of the projecting portions 44 are formed in parallel to the top wall 11a′ and both side walls 11a of the connector housing 11 of the mating connector 10.

When the mating connector 10 is pushed carelessly, the operating portion 43 of the locking arm 40 is pushed and engaging of the mating connector 10 and the connector 30 is released and the mating connector 10 is removed and then electrical disconnecting is occurred. Providing the pair of the projecting portions 44 near the both sides of the locking arm 40, malfunction of above electrical disconnecting can be prevented. Thus, the pair of the projecting portions 44 protects the locking arm 40 so that disconnecting the mating connector 10 from the connector 30 of the camera case 3 carelessly is prevented.

The arm 42 of the locking arm 40 is formed extending rearwardly to the operating portion 43 from the foot portion 41 at the front area of the top wall 11a′ of the connector housing 11 structuring the mating connector 10. An opposite side surface, i.e. a rear surface, of the reference surface 42a of the arm 42 may be formed from front area to rear area to apart gradually from the top wall 11a′ of the connector housing 11 of the mating connector 10.

Preferably, the arm 42 of the locking arm 40 may be formed from the foot portion 41 to the operating portion 43 of the locking arm 40 into convex shape as lightening recess for reducing material cost with keeping mechanical strength of the arm 42.

The arm 42 of the meting connector 10 is provided with a locking projection 45 for engaging with the engaging opening 35 of the connector 30, as shown in FIGS. 1 and 6, correspondingly to the engaging opening 35 of the connector 30 in the camera module Z shown in FIGS. 1, 4 and 5. The locking proj ection 45 as the locking projection 45 is formed on the arm reference surface 42a at the center of the arm 42 shown in FIGS. 1 and 6. The locking projection 45 is provided with a locking surface 45a, a sliding contact surface 45b, a slope sliding contact surface 45c and two side walls 45d.

The locking surface 45a of the locking projection 45 provided on the arm reference surface 42a of the locking arm 40 is formed perpendicularly to the arm reference surface 42a. The locking surface 45a of the locking projection 45 shown in FIGS. 1 and 6 corresponds to the engaging surface 35a of the engaging opening 35 provided in the connector 30 of the camera module Z shown in FIGS. 1, 4 and 5.

The operating portion 43 of the locking arm 40 is formed to project from the arm reference surface 42a of the locking arm 40, as shown in FIGS. 1 and 6. Forming the operating portion 43 into above shape, releasing operation of the locking arm 40 can be done easily by a finger or a tool.

The operating portion 43 of the locking arm 40 is formed into U-shape with a die relieving recess 43a for injection molding. The die relieving recess 43a is required in the molding die structure to form the locking projection 45 and also is provided to reduce weight and material cost of the connector 10.

Such locking and engaging mechanism, as mentioned above, is applied so that the connector 30 of the camera case 3 and the mating connector 10 of the wire harness 4 can be connected and disconnected easily in short time. Thus, the camera module Z in which mated connectors can be electrically connected and disconnected easily in short time can be provided.

The mating connector 10 joined to the wire harness 4 is connected with the connector 30 formed in the camera module Z, as shown in FIG. 1, so that the camera module Z and the wire harness 4 are electrically connected. Mechanism of electrically connecting the mating connector 10 and the connector 30 in camera module Z with engaging or disengaging easily in short time and preventing to be disengaged carelessly will be described.

As the mating connector 10, shown in FIGS. 1 and 6, begins to be inserted into the connector housing 33 of the connector 30 in the camera module Z shown in FIGS. 1, 4 and 5, the foot portion 41 of the locking arm 40 formed on the mating connector 10 begins to be inserted into the connector housing 33 of the connector 30 in the camera module Z.

When the mating connector 10 is inserted more into the connector 30 of the camera module Z, the slope sliding contact surface 45c of the locking projection 45 formed on the locking arm 40 of the mating connector 10 shown in FIG. 6 abuts on the top wall 33a′ of the connector housing 33 in the camera case 3 shown in FIGS. 1, 4 and 5. Describing above action physically with reference to FIGS. 4 and 5, the slope sliding contact surface 45c abuts on a corner edge crossed by an inner surface of the top wall 33a′, including a sliding surface, and a rear surface 34 of the connector housing 33.

When the mating connector 10 is inserted furthermore into the mating connector receiving section 33b of the connector 30 of the camera module Z, the sliding contact surface 45b of the locking projection 45 formed on the locking arm 40 of the mating connector 10 shown in FIG. 6 slides on the sliding surface of the top wall 33a′ of the connector housing 33 in the camera case 3 shown in FIGS. 4 and 5. The mating connector 10 is going into the mating connector receiving section 33b of the connector 30 of the camera module Z in above condition.

In this condition, before engaging with the engaging opening 35 provided in the connector housing 33 of the camera module Z, the resin-made locking arm 40 formed on the mating connector 10 is elastically deformed. In detail, the resin-made locking arm 40 formed on the top wall 11a′ of the mating connector 10 is deflected toward the top wall 11a′ of the connector housing 11 of the mating connector 10 with generated restoring force, in the area of the foot portion 41 and the vicinity, and the full length of the arm 42.

Thereafter, the locking projection 45 formed on the locking arm 40 of the mating connector 10 shown in FIGS. 1 and 6 is sliding on the inner sliding surface of the top wall 33a′ of the connector housing 33 in the camera case 3 shown in FIGS. 4 and 5 to go into the engaging opening 35 provided in the connector housing 33.

In the condition, the deflected resin-made locking arm 40 returns to an original form. Thus, the locking projection 45 formed on the locking arm 40 shown in FIGS. 1 and 6 is engaged with the engaging opening 35 provided in the connector housing 33 shown in FIGS. 1, 4 and 5.

Describing physically, the deflected resin-made locking arm 40 returns to the original form by restoring force charged in the locking arm 40. Therefore, the locking surface 45a of the locking projection 45 formed on the locking arm 40 of the meting connector 10 shown in FIG. 6 and the engaging surface 35a of the engaging opening 35 provided in the connector housing 33 in the camera case 3 shown in FIGS. 4 and 5 abut or face to each other to be engaged securely.

In the condition, the arm reference surface 42a of the locking arm 40 formed on the mating connector 10 shown in FIG. 6 and the inner surface including the sliding surface of the top wall 33a′ of the connector housing 33 shown in FIGS. 4 and 5 abut or face in parallel with a small gap to each other.

If the connector 30 of the camera module Z and the mating connector 10 are mated in such condition, malfunction of electric disconnecting of the camera module Z and the wire harness 4, which is caused by removing the mating connector 10 joined to the wire harness 4 from the connector 30 of the camera module Z when the wire harness 4 is pulled to this side carelessly, can be prevented.

In mating condition, a front surface of the operating portion 43 of the locking arm 40 or a front surface 44a of a slant area of the pair of the projecting portions 44 face to a rear surface 34 provided on the connector housing 33 of the camera module Z with a small gap enabled to be abutted.

If a front surface of the operating portion 43 of the locking arm 40 or a front surface 44a of a slant area of the pair of the projecting portions 44 is provided, connection or disconnection of the mating connector 10 and the connector 30 may be operated satisfyingly and the locking condition can be kept securely and stably.

When the mating connector 10 is inserted into the connector 30 or the mating connector 10 mated with the connector 30 is pushed carelessly, the mating connector 10 may be pushed excessively into the connector 30 of the camera module Z.

However, if a front surface of the operating portion 43 of the locking arm 40 or a front surface 44a of a slant area of the pair of the proj ecting portions 44 face to a rear surface 34 provided on the connector housing 33 of the camera module Z with a small gap enabled to be abutted, the mating connector 10 can not go excessively into the connector 30 of the camera module Z. Then, mating of the connectors may be operated satisfyingly.

Damaging peripheral area of the connector 30 of the camera module Z or components in the camera case 3 joined to the connector 30, or slipping components out of place by pushing the mating connector 10 excessively into the connector 30 of the camera module Z may be not worried. Damaging the mating connector 10 may also be not worried. Malfunction of damaging or slipping components of the camera module Z or the mating connector 10 may be prevented.

Thus, providing the locking projection 45 and the engaging portion 35 having above-mentioned shapes on the male and female connectors, the connectors can be locked securely and stably and good operating feeling of mating the connectors can be done to recognize locking of the connectors. Disconnecting of the connectors also can be done with good operating feeling.

When disconnecting the mating connector 10 joined to the wire harness 4 from the camera module Z, the locking arm is released and the mating connector 10 joined to the wire harness 4 is pulled from the connector 30 of the camera module Z. Describing physically, the operating portion 43 of the resin-made locking arm 40 is pushed toward the top wall 11a′ of the connector housing 11 structuring the mating connector 10 to deflect the resin-made locking arm 40 toward the top wall 11a′ of the connector housing 11 of the mating connector 10.

Thereby, the locking surface 45a of the locking projection 45 formed on the locking arm 40 of the mating connector 10, shown in FIG. 6, is displaced from the position to face the engaging surface 35a of the engaging opening 35 provided in the connector housing 33 of the camera case 3, shown in FIGS. 4 and 5. By pulling the mating connector 10 joined to the wire harness 4 from the connector 30 of the camera case 3 with keeping above condition, the camera module Z and the wire harness 4 can be disconnected easily in short time.

Preferably, the locking projection 45 and the engaging portion 35 may be exchanged in position to be provided on the connector 30 of the camera module Z and the mating connector 10. Preferably, the provided position of the male terminal and the female terminal, or the male connector and the female connector may be also exchanged.

Advantageously, the camera case 3 having the connector housing 33, the plastic portion 6 of the connecting board 5 or the connector housing11 of the mating connector 10 may be formed by injection molding with synthetic resins. Such components are manufactured with synthetic resins which are thermoplastic and can be injection-molded so that the manufacturing is good for mass production and then, the productivity is enhanced to be efficient. Other manufacturing method can be applied preferably correspondingly to component shape.

Advantageously, integrally molding complicated shape components, such as the camera case 3 with the connector housing 33, the connector housing 11 of the mating connector 10 with the locking arm 40 and the lance-shape locking piece, or the plastic portion 6 of the connecting board 5 with the first base board 6a, the second base board 6b and the base board 6c, by synthetic resins which are thermoplastic and can be injection-molded, can be done easily in short time to manufacture volumes.

Above molding components by synthetic resins have preferably good elastic restoring force for the connector housing 11, integrated with the locking arm 40 and the lance-shape locking piece, of the mating connector 10.

When the connector housing 11, integrated with the locking arm 40, of the mating connector 10 is molded with above synthetic resins, and connectors are mated securely by engaging the locking projection 45 (FIGS. 1, 6) formed on the locking arm 40 of the mating connector 10 with the engaging portion 35 (FIGS. 1, 4, 5) provided in the connector housing 33 of the camera case 3, as mentioned above, the above resin-made locking arm 40 can be elastically deformed in the area of the foot portion 41 and the vicinity, and the full length of the arm 42.

After the resin-made locking arm 40 is elastically deformed, the resin-made locking arm 40 returns from deflected condition to the original condition by elastic restoring force at a position in which the locking projection 45 and the engaging portion 35 are engaged.

The engaging condition can be released by deflecting the resin-made locking arm 40 good enough as required. Thus, the connector 30 formed in the auxiliary device module Z, such as the camera module Z, and the mating connector joined to the wire harness 4 can be connected and disconnected easily in short time.

The resin-made connector housing 11 structuring the mating connector 10 is provided, in a terminal receiving section, with a resin-made lance-shape locking piece (not shown) for fixing the female terminal. The lance-shape locking piece is used for fixing the female terminal easily and securely in short time when the female terminal is inserted into the terminal receiving section in the connector housing 11 of the mating connector 10. The lance shape locking piece requires flexibility so that molding the connector housing 11 of the mating connector 10 with the synthetic resin is effective.

Polybutylene terephthalate resin (PBT for short), acrylonitrile butadiene styrene resin (ABS for short), polyamide resin (PA for short) and polypropylene (PP for short) can be used as synthetic resins which are thermoplastic and can be injection-molded. Any kind of fillers can be added therein, if required.

The plastic portion 6 of the connecting board 5, the camera case 3 integrated with the connector housing 33 and the connector housing 11, integrated with the locking arm 40 and the lance shape locking piece, of the mating connector 10, which are molded with polybutylene terephthalate resin (PBT), are excellent in dimensional stability, strength stability and electrical characteristics. An example of polybutylene terephthalate resin (PBT) is PBT-H01. The plastic portion 6 of the connecting board 5 may be formed with a polyamide hot-melt material by injection molding or normal molding.

Molding components, such as the connector housing 11 of the mating connector 10 or the plastic portion 6 of the connecting board 5, may be barrel polished to remove burrs after molding, if required.

Respective corner edges of the camera 1, the auxiliary device base board 2, the camera case 3, the plastic portion 6 of the connecting board 5 and the connector housing 11 of the mating connector 10 are chamfered or filleted, if required. Chamfering means to put a small slant on a corner made with two crossed surfaces. Filleting means to put a small rounding on a corner made with two crossed surfaces.

Chamfering or filleting is for relaxing stress concentration on a corner and for preventing an operator finger, handling the connecting board 5 or the camera module Z, injured by a corner. Chamfering or filleting may be done by barrel polishing.

Any kind of optional components can be mounted on the auxiliary device Z or the junction circuit 5 according to this invention, if required. Some optional components, such as a cover, can be eliminated to reduce number of components. Thereby, the auxiliary device Z, which is miniaturized and weight-saved and then reduced on cost, can be provided.

The auxiliary device module Z according to this invention can be applied for an instrument panel of a car, or a module used in the vicinity of the panel or any other area which can be modularized other than the camera module Z mentioned above.

The camera module Z having a CCD camera 1, as the auxiliary device 1, which is mountable on a car, is preferable for an auxiliary device module Z. The camera module Z is applied as an auxiliary device module according to this invention so that number of components in the camera module Z can be reduced and then, miniaturization, weight-saving and cost reduction of the camera module for a car can be done.

The camera module according to this invention is preferably used as an auxiliary member to ascertain safety of a dead angle to be installed in positions to look from a inside of a vehicle such as a dead angle area in front of a vehicle or rear area of a vehicle such as a normal size car or a large size car like a bus.

When a CCD camera 1 installed on a outside of a car rear area strikes against others during moving back and checking or repairing of the CCD camera 1 is required, a CCD camera 1 according to this invention is easily disassembled and then the damaged CCD camera 1 can be disassembled easily and repaired and reinstalled on the car. Therefore, a module according to this invention is used preferably as a CCD camera 1 for ascertaining visually installed on a outside of a car rear area.

When a camera module Z provided with a CCD camera 1 or related elements installed on a car has a trouble, such as a fault, removing and checking and repairing of the camera module Z are required. A camera module Z according to this invention, which can be easily installed and removed, has good maintainability. Since the camera module Z is disassembled easily, the camera module Z is easily recycled in case of scrapping and then conforms to an environmental issue by industrial waste.

While the forms of the invention herein disclosed constitute presently preferred embodiments, many others are possible. It is not intended herein to mention all the possible embodiments of the invention which will be apparent to those skilled in the art. It is understood that the term used herein are merely descriptive rather than limiting, in that various changes may be made without departing from the spirit or scope of this invention as defined by the following claims.

What is claimed is:

1. A junction circuit for an auxiliary device module comprising:
a first base board having a terminal receiving hole;
a second base board having a terminal receiving hole;
a base board formed integrally with the first base board and the second base board;
a first electric connecting portion provided by inserting a terminal into the terminal receiving hole of the first base board;
a second electric connecting portion provided by inserting other terminal into the terminal receiving hole provided in the second base board; and
a printed wire formed on a flexible base for electrically connecting the terminal of the first electric connecting portion and the other terminal of the second electric connecting portion.

2. The junction circuit for an auxiliary device module according to claim 1, wherein a rear end of the terminal of the first electric connecting portion is connected to an end of the printed wire of the flexible base by soldering, wherein a rear end of the other terminal provided in the second electric connecting portion is connected to the other end of the printed wire of the flexible base by soldering.

3. The junction circuit for an auxiliary device module according to claim 1, wherein the printed wire of the flexible base bent at predetermined portion is connected with the first electric connecting portion and the second electric connecting portion.

4. The junction circuit for an auxiliary device module according to claim 2, wherein the printed wire of the flexible base bent at predetermined portion is connected with the first electric connecting portion and the second electric connecting portion.

5. The junction circuit for an auxiliary device module according to claim 1, 2, 3 or 4, further comprising:
a board mounting hole corresponding to a mounting portion of a device on which the junction circuit for an auxiliary device is mounted.

6. An auxiliary device module comprising:
a base board, having a terminal, on which an auxiliary device is mounted;
a junction circuit having a first electric connecting portion provided with a terminal, a second electric connecting portion provided with other terminal and a base board; and
a case provided with a connector housing corresponding to the first electric connecting portion of the junction circuit, wherein a connector is contained in the case by mounting the first electric connecting portion of the junction circuit on the connector housing of the case, wherein the terminal in the base board and the other terminal mounted in the second electric connecting portion of the junction circuit are connected by mounting the base board on the case.

7. The auxiliary device module according to claim 6, wherein a mating connector having a terminal is electrically connected with the connector, having the terminal, contained in the case.

8. The auxiliary device module according to claim 6, wherein a camera module by using a camera mountable on a car is used for the auxiliary device.

9. The auxiliary device module according to claim 7, wherein a camera module by using a camera mountable on a car is used for the auxiliary device.
